(19) United States
(12) Patent Application Publication
(10) Pub. No.: US 2012/0162945 A1
(43) Pub. Date: Jun. 28, 2012

(54) LABEL HAVING AN ELECTRONIC FUNCTIONAL ELEMENT

(75) Inventor: Helmut Schreiner, Muenchen (DE)

(73) Assignee: SCHREINER GROUP GMBH & CO. KG, Oberschleissheim (DE)

(21) Appl. No.: 13/331,499

(22) Filed: Dec. 20, 2011

(30) Foreign Application Priority Data
Dec. 23, 2010 (DE) 10 2010 056 055.3

(51) Int. Cl. H05K 7/06; H05K 1/02; B32B 37/12; B32B 38/10; B32B 38/18; H05K 1/16; H05K 1/03

(52) U.S. Cl. 361/781; 174/260; 174/256; 174/255; 361/760; 361/783; 156/247; 156/192; 156/60

(57) ABSTRACT

An electronic functional label and a special production process for such a label, which can be equipped with electronic components in very simple, fast, and effective manner, without a soldering process that is connected with high temperatures. For this purpose, a carrier substrate preferably having printed electronic structures is equipped with electronic components by means of an electrically conductive adhesive. The use of special electronic components (sensors and optical/acoustic actors) that interact with their surroundings proves to be particularly advantageous in this connection. High-quality labels, in particular, having surprising interactions can be produced in a simple and cost-advantageous manner.

### CROSS REFERENCE TO RELATED APPLICATIONS

Applicant claims priority under 35 U.S.C. §119 of German Application No. 10 2010 056 055.3 filed Dec. 23, 2010, the disclosure of which is incorporated by reference.

### BACKGROUND OF THE INVENTION

1. Field of the Invention

The present invention relates to a label having an electronic functional component, to its production, as well as to an object provided with such a label. In particular, the present invention relates to a film label having a special electronic additional function, which label can be glued onto an object having a surface of almost any desired shape, in a particularly simple manner, as well as to a production method for such a label.

2. The Prior Art

Nowadays, labels are increasingly being used also as design elements. Specifically, higher-quality products can be additionally optimally upgraded by means of affixing appealing labels. In this way, an additional purchase incentive can be offered in relatively simple manner.

Furthermore, it is also possible, in a relatively simple manner, to impart a different appearance to one and the same product by affixing labels having different designs, by means of using self-adhesive labels. In this way, it is possible to make a product attractive also for different target groups. This in itself makes it clear that self-adhesive labels also have great importance in the sector of marketing and design.

Furthermore, in recent times, labels are increasingly being equipped with additional functions, as well. In this way, further, additional upgrading of the products is possible. For example, the occurrence of different ambient influences, such as, for example, increased humidity or specific temperature variations, can be detected and displayed by means of a label having a sensor element or indicator element.

However, such labels, which provide not only a graphic imprint but also, additionally, electronic additional functions, require a significantly more complex structure and are therefore subject to a clearly more complicated production process. In this connection, it is a further difficulty that components that possess a significantly greater construction height (several millimeters) than the thickness of the carrier film of a label, in itself (several micrometers), are required for the electronic functions.

While it is true that the miniaturization of electronic components continues to advance, surface mounted devices (SMD) available today have a significantly greater construction height in comparison with the thickness of a usual label. This has the result, among other things, that such labels having electronic functional elements cannot be produced using the production equipment that is otherwise used.

Flexible films with conductor tracks applied to them are known, for example, from U.S. Patent Application Publication No. 2009/0314523 A. In this connection, a carrier film composed of polyimide (P1) is provided, on one or even both sides, with conductor tracks composed of copper. As a rule, a conductor track structure is etched out of a full-area copper foil. Contacting and attachment of electronic components takes place, in the case of such a structure, in that the individual components are soldered onto the copper film, and this results in correspondingly high temperatures during the soldering process.

Because of these high temperatures during soldering, special demands are made on the carrier film for such structures. This very greatly restricts the selection of possible materials. In practice, polyimide (trade name “Kapton”) has proven itself as a carrier material for flexible carrier structures. This material is still very resistant even at high temperatures, something that is absolutely necessary particularly during soldering.

On the other hand, this material is also very expensive. Furthermore, a film composed of polyimide also always possesses a yellowish color, and this is viewed as a great disadvantage, particularly when using labels, which generally also possess great optical appeal. Furthermore, the material is also relatively brittle and therefore can only be glued onto surfaces that are greatly curved or domed in a limited manner. Furthermore, this low flexibility is also disadvantageous if such a film substrate is supposed to be wound up onto a roll as tightly as possible, in order to be able to be processed in a roll-to-roll process.

### SUMMARY OF THE INVENTION

It is therefore an object of the present invention to provide a film structure with which an optically appealing label can be configured with electronic functional elements, in a cost-advantageous and efficient manner. For this purpose, it is desirable to be able to use carrier materials for labels that have already established themselves in this sector, and therefore can be processed in this way in a cost-advantageous manner, and which also satisfy the optical and design demands on high-quality labels. In this connection, it should be possible to additionally equip such materials with electronic functional elements in the simplest possible manner, without significant additional costs for further production steps being incurred in this connection. In this connection, processing and component placement of a label according to the invention in a roll-to-roll process is desirable.

This task is accomplished according to the invention by a film element having an electronic functional component. The film element comprises a carrier film having a first and a second side, at least one electrically conductive structure that is imprinted onto the first side of the carrier film by means of applying an electrically conductive printing ink, an electronic component that is applied to the first side of the carrier film, and an electrically conductive adhesive that connects at least one connector contact of the electronic component with the electrically conductive structure.

Furthermore, this object is also accomplished by a method for the production of such a film element having an electrical functional component. This method makes available a carrier film having an electrically conductive structure, whereby the electrically conductive structure is produced from a conductive lacquer applied in a printing process. An electrically conductive adhesive is applied, in part, to the carrier film having the electrically conductive structure. Furthermore, at least one electronic component is dispensed onto the carrier film, whereby an electrically conductive connection between the electrically conductive structure on the carrier film and at least one connector of the electronic component is produced by means of the electrically conductive adhesive.

It is the particular approach of the present invention to propose a structure for an electronic functional label in which optically appealing, cost-advantageous standard film materials can be equipped with electronic functional elements in a simple and efficient method. For this purpose, a carrier substrate that can preferably be processed in a roll-to-roll process is equipped with electronic components, using electrically conductive adhesives. In this way, an appealing and complex label that brings with it excellent additional benefits for numerous application cases can be produced by means of a suitable selection of the electronic components used.

In a special embodiment, the carrier film having the electrically conductive structure is made available as a film web on a roll. Thus, the carrier film can be made available, in a particularly simple manner, for an efficient processing method. The carrier film for the individual labels is then first unwound from the roll, then equipped according to the proposed method, and finally, can be rolled back up onto a roll, together with the components that have been dispensed onto it. Thus, the complete component placement process can be carried out very effectively, using a roll-to-roll process, as is the usual practice, particularly in the printing and label sector.

Alternative to rolling up the labels equipped with components, the individual film elements equipped with components, with the components dispensed onto them, can also be cut off from the cohesive film web in a separation step, and are then present as individual, separate, finished electronic functional labels.

According to a special embodiment of this method, the electrically conductive adhesive is activated and/or cured in a separate step. Thus, after the label film has been equipped with the electronic components, a very rapid process takes place, in which the full adhesive effect of the adhesive being used is achieved. In this connection, it can be necessary for the electronic components to be mechanically fixed in place on the carrier film while the adhesive cures.

In addition, in another method step, an adhesive, preferably a pressure-sensitive adhesive, can be applied to at least one side of the carrier film, at least in part. Thus, a completely self-adhesive portion label is obtained, which can be glued onto almost any desired object in simple manner.

Preferably, the carrier film possesses a first thickness, and the electronic component possesses a second thickness, whereby the second thickness of the electronic component is greater than the first thickness of the carrier film. While the carrier film generally consists of a very thin substrate, the electronic components tend to be elements having a thickness of one to several millimeters, which possess a clearly three-dimensional character.

In special embodiments, the electronic component preferably comprises a battery. Also, the film element can be equipped with an electroluminescence film. Furthermore, it is possible to integrate a loudspeaker or an acoustic signal emitter as an electronic component, so that the electronic functional label emits corresponding signals to the surroundings and thus draws particular attention to itself.

Preferably, the electronic functional label can also be equipped with a sensor, for example a motion sensor. Thus, ambient influences, such as a person coming closer, or the presence of a specific substance, can be detected. Furthermore, the film element can also comprise a switch element, for example a mechanical or also an electronic switch. Furthermore, it is also possible to affix a chip or an integrated circuit on the film element as an electronic component.

It has proved to be particularly advantageous to use one of the materials polyethylene terephthalate, polyethylene naphthalate, polyetherimide, polyether sulfone, acrylate, or polyetheretherketone as a substrate for the carrier film.

In another preferred embodiment, the film element is applied to an object, and at least one electronic component is situated on the side of the film element facing the object. In this way, the electronic functional components of the label are protected from ambient influences and damage. Preferably, the object onto which the functional label is affixed possesses a depression, and the film part is affixed to the object in such a manner that at least one electronic component comes to lie in this depression. In this way, the thicker parts of the electronic components are accommodated in this depression, and toward the outside, the label forms a smooth surface, without elevations, despite the components having a three-dimensional character.

### BRIEF DESCRIPTION OF THE DRAWINGS

Other objects and features of the present invention will become apparent from the following detailed description considered in connection with the accompanying drawings. It is to be understood, however, that the drawings are designed as an illustration only and not as a definition of the limits of the invention.

In the drawings, wherein similar reference characters denote similar elements throughout the several views:

FIG. 1 schematically shows a cross-section through a label structure according to the invention,

FIG. 2 schematically shows a structure of a functional label according to the invention, having multiple components,

FIG. 3 schematically shows a label according to the invention that is affixed to an object,

FIG. 4 schematically shows a functional label according to the invention, having an electroluminescence film, and

FIG. 5 schematically shows a production process for a functional label according to the invention, in a roll-to-roll process.

### DETAILED DESCRIPTION OF THE PREFERRED EMBODIMENT

The following description explains the electronic functional label, as well as its production and use. In this connection, the ideas according to the invention are not restricted to the exemplary embodiments described. Further embodiments that form the basis of the fundamental principle of this invention are also possible.

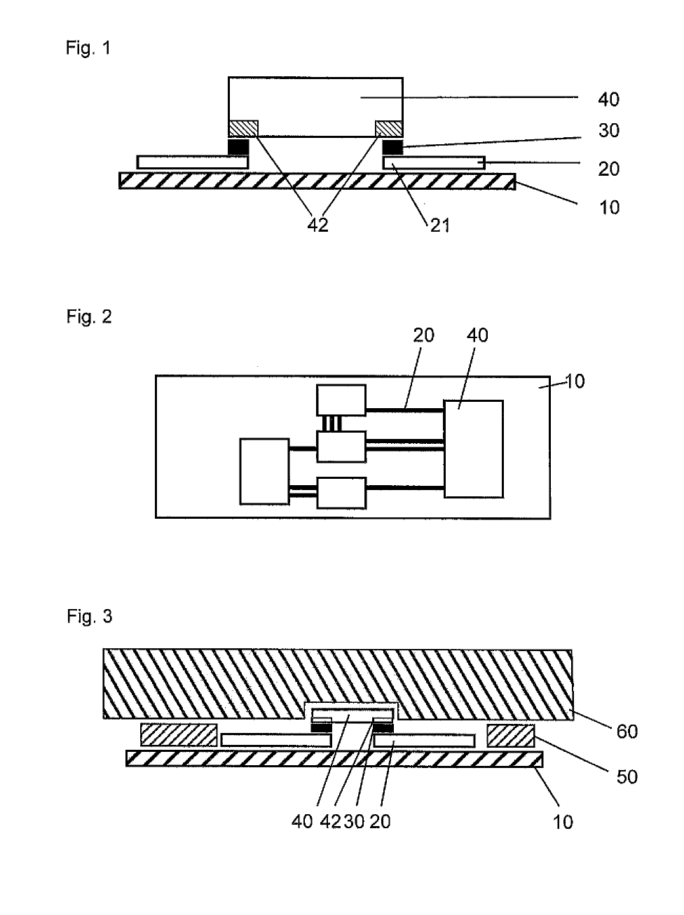

FIG. 1 shows a first embodiment of a film structure 1 according to the invention. First, electrically conductive structures 20 are applied to a film substrate 10. Preferably, these electrically conductive structures 20 are produced by application of an electrically conductive lacquer, using a printing process. For example, silver conductive paste, carbon black, an organic conductive paste, or another substance having conductive particles can be used as an electrically conductive lacquer.

Alternative methods for applying electrically conductive structures to carrier substrate 10 are also possible, however. For example, a copper foil, an ITO coating, or another conductive strip can be laminated on. In order to attach and, at the same time, provide an electrical contact of electronic component 40, an electrically conductive adhesive 30 is applied at contact locations 21 of the conductor tracks 20. In this connection, the adhesive application can take place in a printing method, be laminated on as an adhesive strip, or also applied in another manner.

Subsequently, electronic component 40 is positioned at the desired location and electrically conductive adhesive 30 is cured. Positioning of the component on carrier substrate 10 takes place by means of a suitable special dispensing device. In particular, the component can be laminated on, or can be positioned at the desired location using a pick-and-place method. Electronic component 40 is provided with contact terminals 42 that electrically contact the conductive adhesive 30. By this way, an electrical contact is established between contact terminals 42 of electronic component 40 and conductor tracks 20 through conductive adhesive 30 and contact locations 21 of conductor tracks 20.

In order to be able to fix such a label in place on any desired object, in the simplest possible manner, film substrate 10 is furthermore provided with an adhesive 50, preferably a pressure-sensitive adhesive. This pressure-sensitive adhesive 50 can be applied to the same side of film substrate 10 on which conductor tracks 20 and electronic components 40 are also situated. Alternatively, pressure-sensitive adhesive 50 can also be applied on the side of film substrate 10 that lies opposite conductor tracks 20 and electronic components 40.

Applied adhesive 50 can additionally be covered with a protective film, a so-called liner. Also, it is possible to apply a cover laminate onto the functional label that has been equipped with components. Furthermore, it is also possible to provide the label, coated with adhesive 50, with an adhesive-free touch and pull-off tab.

Preferably, plastics that demonstrate good flexibility are used as materials for the substrate of carrier film 10. In this connection, substrates composed of transparent or white materials are well suited. For example, polyethylene terephthalate (PET), as a particularly cost-advantageous solution, or polyethylene naphthalate (PEN), having somewhat greater temperature stability, have proven to be suitable materials. Of course, almost all other usually used plastic films are possible as a carrier substance for the film structure according to the invention. Other particularly suitable materials are, for example, polyetherimide (PEI), polyether sulfone (PES), polycarbonate (PC), acrylate, or polyetheretherketone (PEEK).

In contrast to the conventional materials that can be used and have been known until now, such as polyimide and the like, which had to be used because of the conventional soldering processes and the relatively high temperatures connected with them, the materials used here are clearly more cost-advantageous and possess significantly better properties with regard to flexibility and optical appearance.

A particularly good optical impression of a label according to the invention can also be achieved in that carrier film 10 is coated with a cover lacquer, at least on one side. Preferably, this cover lacquer is applied on the side that lies opposite the side with conductor tracks 20. In addition or alternatively, carrier film 10 can be provided with writing, symbols, or decorative elements. For example, such optical design elements can be applied using a printing method. Very particularly attractive effects can be achieved by means of additional application of so-called lenticular films (3D/4D films) on the label. Other coatings, particularly for enhancing the optical appearance, or also other methods for configuring the film structure are also possible.

FIG. 2 shows a top view of a label structure according to the invention. In this connection, multiple electronic components 40 are connected with one another by way of conductor tracks 20, and thereby form a complete electronic circuit structure.

In this connection, the individual components can be an energy supply, such as a battery. Also, a photovoltaic element, a so-called solar cell, can be used as an energy supply. Particularly in connection with a relatively small additional energy storage medium, such as a capacitor or a rechargeable battery, for example, an excellent energy supply is thereby obtained, which works for a long time and takes up a minimum of space.

Switch elements, such as a film switch, for example, are also possible. Furthermore, sensor elements, such as a capacitative sensor element or the like, can also be used for input. Electronic output elements, such as a loudspeaker or buzzer, for example, are also possible, as are optical display elements, for example an LED, an electroluminescence film, an organic light-emitting element, or the like. Furthermore, the film structure can also comprise individual discrete electronic components, such as resistors, capacitors, coils, etc., for example. Beyond this, integrated circuits, complete microcontrollers, or pre-finished and, if applicable, encased modules, are also possible.

However, all of these electronic components 40 have the property that they possess a thickness that is slightly to significantly greater than that of the carrier film 10. While the carrier film possesses a thickness of less than 1 mm, often even only a few micrometers, electronic components, even in a miniaturized version, possess a clearly greater thickness, in comparison with carrier film 10, of approximately one to several millimeters. In comparison with the slight thickness of the carrier film 10, such electronic components therefore have a three-dimensional character.

Because no soldering is required for connecting and contacting the electronic components, but rather this process takes place by means of an electrically conductive adhesive, components 40 and also carrier substrate 10 are not exposed to high temperatures. As a result, the elements and materials used are significantly spared.

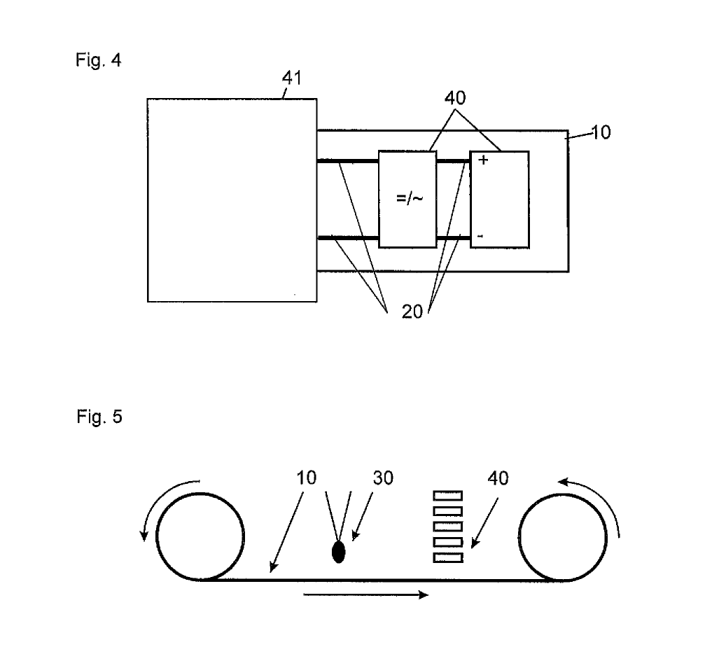

FIG. 3 shows a label according to the invention that is glued onto an object 60. Even though the label structure has a relatively constant thickness over broad parts, the thickness is greater specifically in the region of at least some electronic components. Preferably, this slightly thicker label region comes to lie in a small depression of object 60 to be labeled. In this way, a smooth and homogeneous appearance toward the outside can be guaranteed.

FIG. 4 shows a label structure according to the invention, on the one side of which an electroluminescence film 41 is applied. Contacting of this EL film 41 can take place, in this connection, precisely in the same way, by means of an electrically conductive adhesive as it is also used for the other components 40.

Furthermore, it is also possible that the EL film structure and the remaining label possess a common carrier substrate 10 and thus no adhesive connection between the two parts is needed.

Based on the film structure according to the invention as described above, very particular properties and advantages are obtained, depending on the electronic components 40 used. For example, environmental sensors can also be used as electronic components 40. Thus, depending on the use of a suitable sensor element, a corresponding event can first be detected and, if necessary, be stored in memory and/or displayed. For example, a temperature sensor can respond if a predetermined temperature threshold is exceeded or not reached, and emit a signal. However, other sensors that react to the air pressure or ambient pressure are also possible, as are special sensors that react to the occurrence of a special substance, for example a gas or a liquid, such as water, for example.

When one of the sensors described above responds, an integrated circuit could store this event in memory, together with a corresponding time stamp, and make it available for later evaluation. In addition, an RFID transponder can also be integrated into the label, so that an event protocol of the sensors used can be read out in contact-free manner in this way. Thus, such a label represents a valuable aid, particularly in the logistics sector, when it is a question of protecting sensitive goods during a transport or storage procedure and recognizing undesirable influences. In this way, problems during a transport or storage procedure can be rapidly identified, and goods that might have been damaged can be recognized and sorted out in a timely manner.

Furthermore, it is also possible to integrate a motion alarm into the label structure as a sensor. Such motion sensors generally perceive changes in the infrared range of their surroundings, and pass on a corresponding switching signal in response. If a motion sensor is integrated into the label structure, it is possible, for example, to trigger a special action as soon as a person runs past the label or approaches it. For example, a light-emitting element (for example an EL film) can start to light up, or a signal tone or a melody resonates from the loudspeaker of the label.

Such an electronic functional label is therefore able to react to a person walking by and to draw attention to itself by emitting corresponding optical or acoustic signals. In this way, attractive effects can be achieved, particularly in the sector of advertising, in order to put a specific product very specifically into the center of attention. In this connection, it proves to be particularly advantageous that a label according to the invention can be applied to a product even subsequently, at a later point in time, and thus upgrades this product.

In general, in this connection, the circuit structure with the conductor tracks and the sensors is situated on the “underside” of the label. In other words, a label is glued onto an object 60 in such a manner that the conductor tracks and the electronic components are situated between the object and the carrier film. In this way, the sensors are at first shielded from the outside world by the carrier film 10. Specifically when using sensors, it can be advantageous if the carrier film 10 therefore possesses special openings through which a sensor can enter into contact with the outer environment and can perceive corresponding ambient influences. Such openings can be produced in a simple manner, for example, in that a corresponding, suitable opening is punched into the carrier film 10.

For more complicated or more complex circuit superstructures, it can furthermore also be necessary to apply conductor tracks 20 on both sides of the carrier film 10. These conductor tracks can be printed on both sides or applied in some other manner, so that more complex conductor track structures can be implemented in this way, as well. A connection between the conductor tracks of the two sides can be produced, for example, in that small openings are punched into carrier film 10. These openings can subsequently be filled with conductive lacquer, which is also used for printing conductor tracks 20. In this way, through-contacting between the two sides of carrier film 10 can take place in simple manner.

In the film structure according to the invention, it has proven to be particularly advantageous, in this connection, that the label structure described can be produced in a very simple process method. FIG. 5 shows an embodiment of a production process as to how labels according to the invention can be produced.

For this purpose, carrier substrate 10 is first coated with the electrically conductive structures, in a roll-to-roll process. For example, an electrically conductive lacquer is printed on carrier substrate 10 in a printing process, preferably screen printing. Subsequently, the lacquer is dried or cured. Afterwards, carrier substrate 10 is wound back up onto a roll, and is available for being equipped with electronic components.

In a further process step, the carrier substrate prepared in this way is unwound from the roll. At locations 21, at which components 40 are supposed to be contacted with the conductor tracks, electrically conductive adhesive 30 is subsequently applied to conductor track contacts 21. Subsequently, in a further method step, one or more components 40 is/are precisely positioned on the prepared carrier substrate 10 with adhesive 30. In this connection, adhesive 30 serves as an electrical contact, on the one hand, and, at the same time, as a fixation of component 40 on the film substrate. Subsequently, component 40 still has to be mechanically pressed onto film substrate 10, if necessary, until the adhesive has cured sufficiently. If necessary, this process of curing can be activated or accelerated by means of supplying heat and/or pressure. Other methods for activation and curing of the electrically conductive adhesive are also possible, in this connection. For example, irradiation with UV light, a special chemical substance, or another method can also be used for this purpose.

If necessary, film substrate 10 equipped with components in this way is additionally coated with a pressure-sensitive adhesive 50 and, if necessary, the pressure-sensitive adhesive is covered with a protective film. In this way, a self-adhesive label is obtained, which is equipped with an electronic functional property in a simple manner.

If necessary, a further step can be integrated into this process chain at a suitable point of the production process, in which the film substrate is imprinted in one color or multiple colors. In this way, the label is also given a high-quality optical appearance, in addition to its electronic function.

For protection of electronic components 40 and also of conductor tracks 20, the finished functional label can still be coated with a special protective lacquer or also a very flexible protective laminate. In this way, the relatively sensitive components of the label are protected against damage and, at the same time, the electronics of the label are also protected from being touched by a person.

After a carrier substrate 10 that has been unwound from a roll has been equipped with electronic components 40 and, if applicable, additional components, it can subsequently be wound up onto another roll. Thus, it is possible to make available a large amount of finished, equipped electronic functional labels for a subsequent dispensing process, in very convenient manner. Labels that have been wound up are specifically suitable for an automated dispensing process, because in this way, a great number of labels can be made available in convenient manner.

Alternatively, it is furthermore also possible to separate the individual labels immediately after they are equipped with electronic components 40 and the other process steps that might follow, in other words each individual label is separated from the previously cohesive carrier film 10. For example, this can take place by means of a punching process. The individual, finished functional labels are then present as separate pieces. In this connection, the term punching is here, as also in the rest of the specification, understood to mean both punching using a conventional punch, as well as separation by means of a laser (“laser punching”), or also other commonly used methods.

In summary, this invention describes an electronic functional label and a special production process for such a label. In this connection, the label can be equipped with electronic components in very simple, fast, and effective manner, without a soldering process that is connected with high temperatures. For this purpose, a carrier substrate preferably having printed electronic structures is equipped with electronic components by means of an electrically conductive adhesive. The use of special electronic components (sensors and optical/acoustic actors) that interact with their surroundings proves to be particularly advantageous in this connection. In this manner, high-quality labels, in particular, having surprising interactions can be produced in simple and cost-advantageous manner.

Accordingly, while only a few embodiments of the present invention have been shown and described, it is obvious that many changes and modifications may be made thereunto without departing from the spirit and scope of the invention.

What is claimed is:

1. A film element having an electronic functional component, comprising:
a carrier film having a first side and a second side;
an electrically conductive structure that is imprinted onto the first side of the carrier film by application of an electrically conductive printing ink;
an electronic component that is disposed on the first side of the carrier film, and
an electrically conductive adhesive that connects at least one contact terminal of the electronic component with the electrically conductive structure.

2. The film element according to claim 1, wherein the carrier film possesses a first thickness, and the electronic component possesses a second thickness, and wherein the second thickness of the electronic component is greater than the first thickness of the carrier film.

3. The film element according to claim 1, wherein at least one side of the film element is provided with an adhesive, at least in part.

4. The film element according to claim 1, wherein the electronic component comprises at least a battery.

5. The film element according to claim 1, wherein the film element comprises an electroluminescence film.

6. The film element according to claim 1, wherein the electronic component comprises at least a loudspeaker or an acoustic signal emitter.

7. The film element according to claim 1, wherein the electronic component comprises at least one sensor.

8. The film element according to claim 7, wherein the sensor is a motion sensor.

9. The film element according to claim 1, further comprising at least one switch element connected to the electronic component.

10. The film element according to claim 1, wherein the electronic component comprises at least one integrated circuit or a chip.

11. The film element according to claim 1, wherein the carrier film is made from a material selected from the group consisting of polyethylene terephthalate, polyethylene naphthalate, polyetherimide, polyether sulfone, polycarbonate, acrylate, and polyetheretherketone.

12. An object comprising a film element having an electronic functional component, the film element comprising:
a carrier film having a first side and a second side;
an electrically conductive structure that is imprinted onto the first side of the carrier film by application of an electrically conductive printing ink;
at least one electronic component that is applied to the first side of the carrier film; and
an electrically conductive adhesive that connects at least one connector contact of the at least one electronic component with the electrically conductive structure,
wherein the film element is applied to the object in such a manner that said at least one electronic component is situated on the side of the film element facing the object.

13. The object according to claim 12, wherein the carrier film possesses a depression, and the film part is affixed to the object in such a manner that the at least one electronic component comes to lie in said depression.

14. A method for the production of a film element having an electronic functional component, comprising:
providing a carrier film having at least one electrically conductive structure, wherein the electrically conductive structure is produced from a conductive lacquer applied in a printing process;
applying an electrically conductive adhesive to a portion of the carrier film having the electrically conductive structure, and
dispensing at least one electronic component onto the carrier film, wherein an electrically conductive connection between the electrically conductive structure on the carrier film and at least one contact terminal of the at least one electronic component is produced by means of the electrically conductive adhesive.

15. The method according to claim 14, wherein the carrier film is provided on a roll, as a film web having the electrically conductive structure.

16. The method according to claim 15, further comprising the step of rolling up the carrier film, together with the at least one component dispensed onto it.

17. The method according to claim 15, further comprising separating a film element having at least one electronic component dispensed thereon from the film web.

18. The method according to claim 14, further comprising curing the electrically conductive adhesive.

19. The method according to claim 18, wherein the component is mechanically fixed in place on the carrier film during curing.

20. The method according to claim 14, further comprising applying an adhesive to at least a portion of the carrier film.
